(19) United States
(12) Patent Application Publication
(10) Pub. No.: US 2020/0255974 A1
(43) Pub. Date: Aug. 13, 2020

(54) Method of Manufacturing Crystalline Gallium Nitride Film

(71) Applicants: National University Corporation Tokyo University of Agriculture and Technology, Tokyo (JP); Taiyo Nippon Sanso Corporation, Tokyo (JP)

(72) Inventors: Akinori Koukitu, Fuchu-shi, Tokyo (JP); Hisashi Murakami, Fuchu-shi, Tokyo (JP); Akira Yamaguchi, Tsukuba-shi, Ibaraki (JP)

(73) Assignees: National University Corporation Tokyo University of Agriculture and Technology, Tokyo (JP); Taiyo Nippon Sanso Corporation, Tokyo (JP)

(21) Appl. No.: 16/646,792

(22) PCT Filed: Sep. 13, 2018
(86) PCT No.: PCT/JP2018/033982

§ 371 Date: Mar. 12, 2020

(30) Foreign Application Priority Data
Sep. 14, 2017 (JP) 2017-177097

(51) Int. Cl. C30B 25/16; C30B 29/40

(52) U.S. Cl. CPC C30B 25/165; C30B 29/406

(57) ABSTRACT

A method of manufacturing a crystalline gallium nitride film, including: a growth step in which a GaCl₃ gas, a halogen gas, an NH₃ gas, and a carrier gas consisting of one or more inert gases are supplied onto a substrate, thereby growing a crystalline gallium nitride film on the substrate, wherein a partial pressure ratio [P_{Halogen}/P_{GaCl3}] is defined as a ratio of a partial pressure of the halogen gas with respect to a partial pressure of the GaCl₃ gas on the substrate in the growth step, and the partial pressure ratio [P_{Halogen}/P_{GaCl3}] is 0.20 or more.

### TECHNICAL FIELD

The present disclosure relates to a method of manufacturing a crystalline gallium nitride film.

### BACKGROUND ART

Hydride vapor phase epitaxy (HVPE) where crystalline gallium nitride films are manufactured by reaction of gallium monochloride (GaCl) gases with ammonia (NH₃) gases is known as one of methods of manufacturing crystalline gallium nitride films.

Patent Document 1 discloses a method of forming a crystalline gallium nitride film by reaction of a gallium trichloride (GaCl₃) gas with an ammonia (NH₃) gas, as a method capable of manufacturing a crystalline gallium nitride film at a high growth rate as compared with the HVPE.

Patent Document 1: WO 2011/142402

### SUMMARY OF INVENTION

### Technical Problem

The method of manufacturing a crystalline gallium nitride film by reaction of a GaCl gas with an NH₃ gas is called HVPE, whereas the method of forming a crystalline gallium nitride film by reaction of a GaCl₃ gas with an NH₃ gas, described in Patent Document 1, is called THVPE (Tri-Halide Vapor Phase Epitaxy).

HVPE and THVPE are different in terms of not only the type of a raw material gas, but also a carrier gas used. Specifically, the carrier gas used in HVPE is a hydrogen (H₂) gas, or a mixed gas of a hydrogen gas and a nitrogen gas (N₂), whereas the carrier gas used in THVPE is an inert gas.

The manufacturing of a crystalline gallium nitride film according to HVPE is a technique established to some extent, whereas THVPE is a newer technique than HVPE.

Accordingly, some of manufacturing conditions of a crystalline gallium nitride film according to THVPE are still unknown, and such manufacturing conditions can be even further improved.

An object of the disclosure is to provide a method of manufacturing a crystalline gallium nitride film, which is a method of manufacturing a crystalline gallium nitride film according to THVPE and which is high in growth rate as compared with a conventional method of manufacturing a crystalline gallium nitride film according to THVPE.

### Solution to Problem

Specific solutions for solving the above problems encompass the following aspects.
<1> A method of manufacturing a crystalline gallium nitride film, including:

a growth step in which a GaCl₃ gas, a halogen gas, an NH₃ gas, and a carrier gas consisting of one or more inert gases are supplied onto a substrate, thereby growing a crystalline gallium nitride film on the substrate,

wherein a partial pressure ratio [P_{Halogen}/P_{GaCl3}] is defined as a ratio of a partial pressure of the halogen gas with respect to a partial pressure of the GaCl₃ gas on the substrate in the growth step, and the partial pressure ratio [P_{Halogen}/P_{GaCl3}] is 0.20 or more.
<2> The method of manufacturing a crystalline gallium nitride film according to <1>, wherein the partial pressure ratio [P_{Halogen}/P_{GaCl3}] is 0.30 or more.
<3> The method of manufacturing a crystalline gallium nitride film according to <1> or <2>, wherein the partial pressure ratio [P_{Halogen}/P_{GaCl3}] is 2.50 or less.
<4> The method of manufacturing a crystalline gallium nitride film according to any one of <1> to <3>, wherein supply of the GaCl₃ gas onto the substrate and supply of the halogen gas onto the substrate are substantially simultaneously started in the growth step.
<5> The method of manufacturing a crystalline gallium nitride film according to any one of <1> to <4>, wherein a mixed gas including the GaCl₃ gas, the halogen gas, and the carrier gas consisting of one ore more inert gases, and a mixed gas including the NH₃ gas and the carrier gas consisting of one or more inert gases onto the substrate in the growth step.
<6> The method of manufacturing a crystalline gallium nitride film according to any one of <1> to <5>, wherein the halogen gas is a Cl₂ gas.
<7> The method of manufacturing a crystalline gallium nitride film according to any one of <1> to <6>, wherein the temperature of the substrate in the growth step is from 1200° C. to 1550° C.

### Advantageous Effect of Invention

The disclosure provides a method of manufacturing a crystalline gallium nitride film, wherein the method provides high growth rate as compared with a conventional method of manufacturing a crystalline gallium nitride film according to THVPE.

### BRIEF DESCRIPTION OF DRAWINGS

FIG. 1 shows a schematic configuration view illustrating one example of a crystalline gallium nitride film-manufacturing apparatus for use in the manufacturing method of the disclosure.

FIG. 2 shows a schematic configuration view illustrating one example of a GaCl₃ gas production apparatus with solid GaCl₃ as a raw material.

FIG. 3 shows a schematic configuration view illustrating one example of a GaCl₃ gas production apparatus with liquid Ga as a raw material.

FIG. 4 shows an appearance photograph of a susceptor in the case of manufacturing a Crystalline GaN film onto a substrate in a condition of a partial pressure ratio [P_{Halogen}/P_{Gacl3}] of 0 in Experimental Example 5.

FIG. 5 shows a photoluminescence (PL) spectrum of a yellowish-white powder attached to the outer periphery of a susceptor in the case of manufacturing a Crystalline GaN film onto a substrate in a condition of a partial pressure ratio [P_{Halogen}/P_{GaCl3}] of 0 in Experimental Example 5.

FIG. 6 shows an appearance photograph of a susceptor in the case of manufacturing a Crystalline GaN film onto a substrate in a condition of a partial pressure ratio [P_{Halogen}/P_{GaCl3}] of 0.20 in Experimental Example 5.

FIG. 7 shows an appearance photograph of a susceptor in the case of manufacturing a Crystalline GaN film onto a substrate in a condition of a partial pressure ratio [P_{Halogen}/P_{GaCl3}] of 1.00 in Experimental Example 5.

### DESCRIPTION OF EMBODIMENTS

A numerical value range herein represented by “(from) . . . to . . . ” in the description means that the range encompasses respective numerical values described before and after “to” as a lower limit value and an upper limit value, respectively.

The term “step” herein encompasses not only an independent step, but also a step which can achieve a predetermined object even in the case of being not clearly distinguished from other steps.

The method of manufacturing a crystalline gallium nitride film of the disclosure (hereinafter, also referred to as “the manufacturing method of the disclosure”) includes a growth step in which a GaCl₃ gas, a halogen gas, an NH₃ gas, and a carrier gas consisting of an inert gas are supplied onto a substrate, thereby growing a crystalline gallium nitride film on the substrate, wherein a partial pressure ratio [P_{Halogen}/P_{GaCl3}] is defined as a ratio of the partial pressure of the halogen gas with respect to a partial pressure of the GaCl₃ gas on the substrate in the growth step, and the partial pressure ratio [P_{Halogen}/P_{GaCl3}] is 0.20 or more.

The manufacturing method of the disclosure is a method of manufacturing a crystalline gallium nitride film according to THVPE, in which an inert gas is used as a carrier gas and a GaCl₃ gas is used as a raw material gas.

The manufacturing method of the disclosure has an effect of allowing the growth rate (namely, the amount of increase in thickness per unit time) to be high as compared with a conventional method of manufacturing a crystalline gallium nitride film according to THVPE.

While the reason why the effect is exerted is not clear, the following reason supposed is considered, provided that the manufacturing method of the disclosure is not limited by the following reason supposed.

THVPE allows a crystalline gallium nitride (GaN) film to be grown by reaction of a gallium trichloride (GaCl₃) gas as a raw material gas with an ammonia (NH₃) gas as a raw material gas. The scheme of the reaction is as follows:

GaCl₃(g)+NH₃(g)→GaN(s)+3HCl(g)

where (g) represents gaseous and (s) represents solid.

The present inventors have made intensive studies, and as a result, have obtained the following finding based on, for example, Experimental Examples 1 to 5 described below.

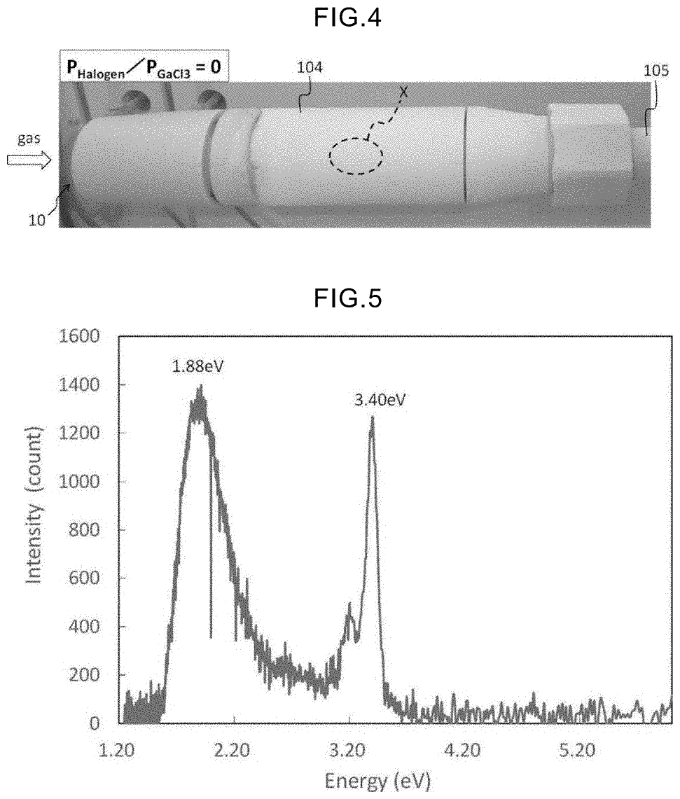

The reaction is high in reaction rate, and thus may sometimes occur not only on a substrate, where is an objective, but also in a vapor phase before arriving at the substrate. In a case in which the reaction occurs on the substrate, GaN(s) is produced as a crystalline gallium nitride film (hereinafter, also referred to as “Crystalline GaN film”) being an objective product. In a case in which the reaction occurs in a vapor phase, GaN(s) is produced as GaN particles (see, for example, Experimental Example 5, and FIG. 4 and FIG. 5, described below).

In other words, in a case in which the reaction occurs in a vapor phase in manufacturing of a Crystalline GaN film according to THVPE, the GaCl₃ gas as a raw material gas is partially consumed for production of not the Crystalline GaN film being an objective product, but such a GaN particle. In other words, the GaCl₃ gas as a raw material gas is partially consumed wastefully (see, for example, Experimental Example 5 described below).

The inventors have made further studies, and as a result, have found that, in a case in which a halogen gas is supplied a onto a substrate, in addition to GaCl₃ gas, in particular, in a case in which the above partial pressure ratio [P_{Halogen}/P_{GaCl3}] is 0.20 or more, the growth rate of a crystalline gallium nitride film is remarkably increased.

The inventors have also found that, in a case in which the partial pressure ratio [P_{Halogen}/P_{GaCl3}] is 0.20 or more, the reaction in a vapor phase (namely, production of such a GaN particle) is suppressed.

According to the manufacturing method of the disclosure, the partial pressure ratio [P_{Halogen}/P_{GaCl3}] is set to 0.20 or more based on the foregoing finding, thereby allowing the reaction in a vapor phase (namely, wasted consumption of the GaCl₃ gas) to be suppressed and allowing the GaCl₃ gas to be efficiently utilized for growth of a Crystalline GaN film on the substrate. Thus, the manufacturing method of the disclosure has the effect of allowing the growth rate to be high as compared with a conventional method of manufacturing a Crystalline GaN film according to THVPE.

While the reason why the reaction in a vapor phase is suppressed in the manufacturing method of the disclosure is not clear, the following reason supposed is considered.

It is considered with respect to the manufacturing method of the disclosure that a halogen gas is supplied onto the substrate in addition to the GaCl₃ gas and the partial pressure ratio [P_{Halogen}/P_{GaCl3}] is set to 0.20 or more, thereby allowing a molecule (for example, an adduct product) to be produced by an NH₃ gas which is try to react with the GaCl₃ gas, and such a halogen gas (for example, Cl₂ gas) in a vapor phase. It is considered that production of such a molecule suppresses the reaction “GaCl₃(g)+NH₃(g)→GaN(s)+3HCl(g)” and does not cause production of GaN in a vapor phase to occur.

It is considered that GaCl₃ subsequently arrives at and adsorbs to the substrate and an NH₃ gas present in a large amount is diffused onto the substrate, thereby allowing GaCl₃ and NH₃ to react on the substrate and growing a Crystalline GaN film on the substrate.

It is considered with respect to the manufacturing method of the disclosure that wasted consumption of a raw material gas (GaCl₃) is thus suppressed and a raw material gas (GaCl₃) is efficiently utilized for growth of the Crystalline GaN film being an objective product. As a result, the growth rate is increased as compared with a conventional method of manufacturing a crystalline gallium nitride film according to THVPE.

The manufacturing method of the disclosure is not particularly limited with respect to other conditions than the above conditions as long as the method satisfies the above conditions.

The manufacturing method of the disclosure can be performed by use of any apparatus known as a crystalline gallium nitride film-manufacturing apparatus according to THVPE.

Specific examples of such a manufacturing apparatus will be described below.

The substrate which can be used in the manufacturing method of the disclosure is, for example, a monocrystalline substrate such as a sapphire (0001) substrate, a silicon carbide substrate, or a gallium nitride substrate.

The inert gas as the carrier gas in the manufacturing method of the disclosure is preferably a nitrogen (N₂) gas, a helium (He) gas, a neon (Ne) gas, or an argon (Ar) gas. Such gases may also be used as a mixture of two or more kinds thereof.

The halogen gas in the manufacturing method of the disclosure is preferably a fluorine (F₂) gas, a chlorine (Cl₂) gas, or a bromine (Br₂) gas, particularly preferably a chlorine (Cl₂) gas.

The halogen gas in the manufacturing method of the disclosure may be a single gas including one kind thereof, or may be a mixed gas of two or more kinds thereof.

Needless to say, the concept “halogen gas” here mentioned does not encompass any hydrogen halide gas (HCl gas, HBr gas, HI gas, or the like).

The partial pressure ratio [P_{Halogen}/P_{GaCl3}] in the manufacturing method of the disclosure is 0.20 or more. Thus, the growth rate of a Crystalline GaN film is increased.

The partial pressure ratio [P_{Halogen}/P_{GaCl3}] is preferably 0.30 or more from the viewpoint of a more increase in the growth rate of a Crystalline GaN film.

The upper limit of the partial pressure ratio [P_{Halogen}/P_{GaCl3}] in the manufacturing method of the disclosure is not particularly limited.

The partial pressure ratio [P_{Halogen}/P_{GaCl3}] is, for example 3.00 or less.

The partial pressure ratio [P_{Halogen}/P_{GaCl3}] is preferably 2.50 or less, more preferably 2.00 or less from the viewpoint of a more increase in the growth rate of a Crystalline GaN film.

The “partial pressure ratio [P_{Halogen}/P_{GaCl3}]” (namely, the ratio of the partial pressure of the halogen gas with respect to the partial pressure of the GaCl₃ gas on the substrate) herein means the ratio of the partial pressure of the halogen gas to the partial pressure of the GaCl₃ gas at a location at a distance of 40 mm away from the substrate toward the gas upstream (namely, the side fromwhich a gas such as the GaCl₃ gas is supplied).

It is preferable that supply of the GaCl₃ gas onto the substrate and supply of the halogen gas onto the substrate are substantially simultaneously started in the growth step.

In a case in which supply of the GaCl₃ gas onto the substrate and supply of the halogen gas onto the substrate are substantially simultaneously started, etching of the substrate by the halogen gas is more suppressed and the occurrence of a crystal defect on a Crystalline GaN film, due to such etching, is more suppressed than a case in which supply of the halogen gas onto the substrate is started before supply of the GaCl₃ gas onto the substrate.

In a case in which supply of the GaCl₃ gas onto the substrate and supply of the halogen gas onto the substrate are substantially simultaneously started, the reaction of formation of GaN in a vapor phase is more suppressed and consequently the growth rate of a Crystalline GaN film on the substrate is more increased than a case in which supply of the halogen gas onto the substrate is started after supply of the GaCl₃ gas onto the substrate.

The term “substantially simultaneously” means that the difference between the start time of supply of the GaCl₃ gas onto the substrate and the start time of supply of the halogen gas onto the substrate is from 0 seconds to 2 seconds. The difference between the start time of supply of the GaCl₃ gas onto the substrate and the start time of supply of the halogen gas onto the substrate is preferably from 0 seconds to 1 second.

Examples of a preferable mode with respect to the growth step include a mode where supply of the GaCl₃ gas onto the substrate and supply of the halogen gas onto the substrate are performed by use of a gas release member which releases at least the GaCl₃ gas and the halogen gas toward the substrate.

The gas release member may be any member which releases at least the GaCl₃ gas and the halogen gas toward the substrate, and may also release the carrier gas toward the substrate, in addition to the GaCl₃ gas and the halogen gas. The gas release member may also further release the ammonia gas toward the substrate.

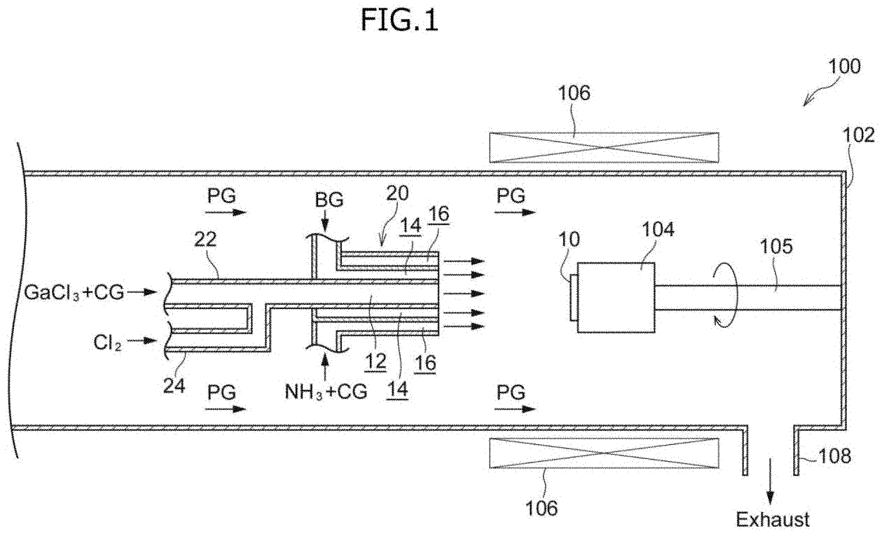

One example of the gas release member is a gas release member 20 (FIG. 1) described below.

In a case in which supply of the GaCl₃ gas onto the substrate and supply of the halogen gas onto the substrate are performed by use of the gas release member, the start time of supply of the GaCl₃ gas onto the substrate means any time at which release of the GaCl₃ gas from the gas release member is started, and the start time of supply of the halogen gas onto the substrate means any time at which release of the halogen gas from the gas release member is started.

Examples of a preferable mode with respect to the growth step include a mode where a mixed gas which includes: a carrier gas consisting of one or more inert gases; a GaCl₃ gas; and a halogen gas (hereinafter, also referred to as “mixed gas A”) and a mixed gas which includes a carrier gas consisting of one or more inert gases, and a NH₃ gas (hereinafter, also referred to as “mixed gas B”) are supplied onto the substrate.

According to such a mode, the reaction of the GaCl₃ gas with the NH₃ gas in a vapor phase is mode suppressed.

Respective preferable modes of the inert gas in the mixed gas A and the inert gas in the mixed gas B are as described above.

A temperature of the substrate in the growth step (hereinafter, also referred to as “growth temperature”), which can be appropriately applied, is any usual growth temperature in THVPE.

The growth temperature is preferably from 1200° C. to 1550° C.

[One Example of Crystalline Gallium Nitride Film-Manufacturing Apparatus]

The manufacturing method of the disclosure can be performed by use of a known apparatus, without any particular limitation, as a crystalline gallium nitride film-manufacturing apparatus according to THVPE.

While one example of the crystalline gallium nitride film-manufacturing apparatus for use in the manufacturing method of the disclosure will be shown below, the crystalline gallium nitride film-manufacturing apparatus for use in the manufacturing method of the disclosure, is not limited to the following one example.

FIG. 1 is a schematic configuration view illustrating a Crystalline GaN film-manufacturing apparatus 100 as one example of the crystalline gallium nitride film-manufacturing apparatus for use in the manufacturing method of the disclosure.

The Crystalline GaN film-manufacturing apparatus 100 illustrated in FIG. 1 is a crystalline gallium nitride film-manufacturing apparatus according to THVPE.

The Crystalline GaN film-manufacturing apparatus 100 includes a tubular housing 102 and a susceptor 104 disposed in the housing 102, as illustrated in FIG. 1.

The susceptor 104 is rotatably supported on one end in the longitudinal direction of the inner wall of the housing 102, with a rotational shaft 105 being interposed.

A substrate 10 is mounted on the susceptor 104, and a Crystalline GaN film is grown on the substrate 10 (on the left surface of the substrate 10 in FIG. 1).

Examples of the material of the housing 102 include quartz, sapphire, and silicon carbide (SiC).

Examples of the material of the susceptor 104 include ceramics (for example, a composite sintered product of silicon nitride and boron nitride).

A heater 106 which heats the substrate 10, the susceptor 104, and peripheries thereof (namely, also referred to as “growth section”) is disposed on the circumference of the housing 102.

The growth of a Crystalline GaN film is performed in a state where the entire growth section including the substrate 10 is heated by the heater 106. The heater 106 which can be used is, for example, a heater of a high-frequency heating system (high-frequency oscillation coil or the like).

A heating unit not illustrated (for example, an induction heating apparatus such as pBN-coating carbon) may also be provided on the inner wall of the housing 102 in the growth section, instead of the heater 106 or in addition to the heater 106, and the heating unit may also heat the growth section.

A cooling unit not illustrated (water-cooling apparatus, air-cooling apparatus, or the like) which prevents the temperature of the housing 102 itself from being too high may also be provided on the inner wall and/or the outer wall of the housing 102 in the growth section.

The method of heating the growth section is not particularly limited. In fact, the method is not particularly limited as long as the substrate 10 can be heated to a desired growth temperature.

The growth temperature means the temperature of the substrate 10 in the growth step.

The growth temperature is preferably from 1200° C. to 1550° C.

A gas release member 20 which releases a raw material gas toward the substrate 10 is disposed at a location in the housing 102, the location facing the substrate 10.

The raw material gas means a gas serving as a raw material of a Crystalline GaN film.

The raw material gas specifically corresponds to a GaCl₃ gas serving as a Ga source of a Crystalline GaN film and an NH₃ gas serving as a N source of a Crystalline GaN film.

The gas release member 20, when viewed from a location where the raw material gas is released, includes a central release section 12 located at the center, an intermediate release section 14 located on the circumference of the central release section 12, and an outer periphery release section 16 located on the circumference of the intermediate release section 14.

A mixed gas including a GaCl₃ gas, a Cl₂ gas, and a carrier gas CG is released from the central release section 12 of the gas release member 20 toward the substrate 10.

Hereinafter, this point will be described in detail.

The central release section 12 is in communication with one end of a GaCl₃ supply tube 22. Other end of the GaCl₃ supply tube 22 is connected to a GaCl₃ gas production section not illustrated.

One end of a halogen gas supply tube 24 is connected to a midstream of the GaCl₃ supply tube 22. Other end of the halogen gas supply tube 24 is connected to a halogen gas supply unit not illustrated.

A GaCl₃ gas produced in the GaCl₃ gas production section (not illustrated) is supplied to the GaCl₃ supply tube 22, together with the carrier gas CG.

A Cl₂ gas as a halogen gas is supplied to the GaCl₃ supply tube 22 further via the halogen gas supply tube 24. The Cl₂ gas may be supplied in a state of being diluted with the carrier gas. The GaCl₃ gas, the Cl₂ gas, and the carrier gas CG are mixed in the GaCl₃ supply tube 22 and formed into a mixed gas. The mixed gas is sent to the central release section 12, and released from the central release section 12 toward the substrate 10.

A variation of the Crystalline GaN film-manufacturing apparatus 100 may allow not only the GaCl₃ gas and the carrier gas CG, but also the halogen gas to be supplied to the GaCl₃ supply tube 22. In other words, a mixed gas of the GaCl₃ gas, the halogen gas, and the carrier gas CG may be supplied to the GaCl₃ supply tube 22. In such a case, the halogen gas supply tube 24 connected to the GaCl₃ supply tube 22 can also be omitted.

Examples of the method of supplying the halogen gas to the GaCl₃ supply tube 22 include a method including introducing an excess amount (namely, excess amount over an amount necessary for production of the GaCl₃ gas) of the Cl₂ gas through a Cl₂ inlet 44 in a GaCl₃ gas production apparatus 40 (FIG. 3) described below, thereby transporting a mixed gas of the produced GaCl₃ gas, an excess Cl₂ gas, and the carrier gas CG to the downstream of a reaction tube 42.

The carrier gas CG here used, to be supplied together with the GaCl₃ gas, is an inert gas.

The inert gas is preferably a nitrogen (N₂) gas, a helium (He) gas, an argon (Ar) gas, or a nitrogen gas.

A barrier gas BG is released from the intermediate release section 14 of the gas release member 20. The barrier gas BG is supplied from a barrier gas supply unit not illustrated, to the intermediate release section 14.

The barrier gas BG here used is the same inert gas as the above carrier gas CG.

The barrier gas BG is located between the GaCl₃ gas and the NH₃ gas in the gas release member 20. The function of the barrier gas BG corresponds to a function which inhibits a GaN particle from being formed by reaction of the GaCl₃ gas and the NH₃ gas near the exit of the gas release member 20.

The barrier gas BG is substantially the same as the carrier gas CG except that the function is different.

Not only the barrier gas BG, but also the halogen gas may be allowed to flow through the intermediate release section 14.

The NH₃ gas and the carrier gas CG are released from the outer periphery release section 16 of the gas release member 20.

The NH₃ gas is supplied, together with the carrier gas CG, to the outer periphery release section 16 with an NH₃ supply unit not illustrated.

The GaCl₃ gas, the Cl₂ gas, the NH₃ gas, the carrier gas CG, and the barrier gas BG are released from the gas release member 20 toward the substrate 10, as described above.

The GaCl₃ gas and the Cl₂ gas are exhausted in the form of a mixed gas including the GaCl₃ gas and the Cl₂ gas.

A Crystalline GaN film is formed on the substrate 10, with the GaCl₃ gas and the NH₃ gas as raw material gases.

The Cl₂ gas has a function which inhibits the GaCl₃ gas and the NH₃ gas from reacting in a vapor phase and thus enhances the rate of formation of a Crystalline GaN film, as described above.

The distance between the outlet of each gas in the gas release member 20 and the substrate 10 is preferably from 50 mm to 200 mm, more preferably from 50 mm to 150 mm, particularly preferably from 50 mm to 100 mm.

The Crystalline GaN film-manufacturing apparatus 100 includes a mechanism (not illustrated) which is provided in the housing 102 and which allows a purge gas PG to flow in a direction from the gas release member 20 toward the substrate 10, and an exhaust port 108 which exhausts any gas in the housing 102. Such structures produce a flow current in a direction from the gas release member 20 toward the substrate 10, and such a flow current suppresses any back current (namely, a current from the flow substrate 10 toward the gas release member 20) of the raw material gas. As a result, the rate of formation of a Crystalline GaN film is more increased.

The purge gas PG is substantially the same gas (namely, inert gas) as the carrier gas CG except that the function is different.

The Crystalline GaN film-manufacturing apparatus 100 may, of course, appropriately include a member usually used in the Crystalline GaN film-manufacturing apparatus, besides the above members.

For example, the apparatus may include a pressure measurement unit (for example, pressure gauge) which measures the total pressure and/or the partial pressure of each gas, and/or a temperature measurement unit (thermometer, thermocouple, or the like) which measures the atmosphere temperature and/or the substrate temperature, in the housing 102.

Each pipe may be provided with a valve which performs supply of each gas and stop of such supply.

Next, one example of a process of manufacturing a Crystalline GaN film by use of the Crystalline GaN film-manufacturing apparatus 100 is shown.

In such one example, the exhaust port 108 of the housing 102 is normally opened and a purge gas PG is also allowed to normally flow in the housing 102. Such a state is defined as the initial state.

First, a barrier gas BG is supplied to the intermediate release section 14 of the gas release member 20, and the barrier gas BG supplied is released from the intermediate release section 14 toward the substrate 10.

Next, an NH₃ gas and a carrier gas CG are supplied to the outer periphery release section 16 of the gas release member 20, and the NH₃ gas and the carrier gas CG supplied are released from the outer periphery release section 16 toward the substrate 10.

Next, the growth section is heated, whereby the substrate 10 is heated to a desired growth temperature.

After the substrate 10 is heated to such a desired growth temperature, supply of a GaCl₃ gas and a carrier gas CG to the GaCl₃ supply tube 22 (hereinafter, designated as “supply 1”) and supply of a Cl₂ gas (or Cl₂ gas diluted with the carrier gas) via the halogen gas supply tube 24 to the GaCl₃ supply tube 22 (hereinafter, designated as “supply 2”) are started. The timing between the start of supply 1 and the start of supply 2 is adjusted, whereby supply of a GaCl₃ gas onto the substrate 10 and supply of a Cl₂ gas onto the substrate 10 are substantially simultaneously started. Thus, manufacturing of a Crystalline GaN film onto the substrate 10 (namely, growth step) is started. A Crystalline GaN film is manufactured for a desired period in such a state.

Termination of such manufacturing of a Crystalline GaN film is performed by substantially simultaneously stopping the supply of a GaCl₃ gas and a carrier gas CG and the supply of a Cl₂ gas and a carrier gas CG.

[Specific Example of GaCl₃ Gas Production Section]

Examples of the GaCl₃ gas production section in the apparatus for manufacturing a Crystalline GaN film (Crystalline GaN film-manufacturing apparatus) include a GaCl₃ gas production apparatus A with solid GaCl₃ as a raw material, and a GaCl₃ gas production apparatus B with liquid Ga as a raw material.

<GaCl₃ Gas Production Apparatus A with Solid Ga as Raw Material>

The GaCl₃ gas production apparatus A with solid GaCl₃ as a raw material, which can be used, is a GaCl₃ gas production apparatus A which produces a GaCl₃ gas as steam produced from GaCl₃.

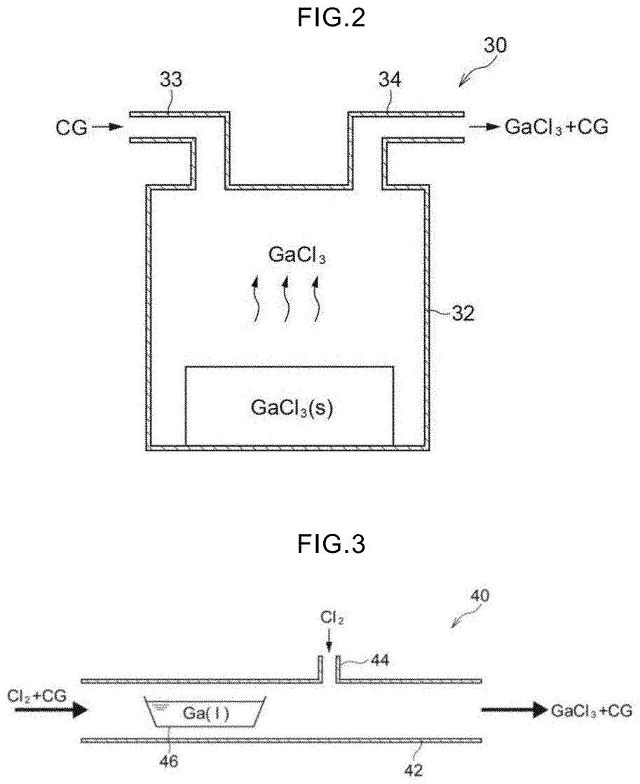

FIG. 2 is a schematic configuration view illustrating one example of the GaCl₃ gas production apparatus A.

A GaCl₃ gas production apparatus 30 as one example of the GaCl₃ gas production apparatus A includes a vessel 32 which accommodates GaCl₃(s) (namely, solid GaCl₃) therein, as illustrated in FIG. 2.

The vessel 32 includes a heating unit (not illustrated) such as a heater. The solid GaCl₃ is heated, whereby a GaCl₃ gas is produced as steam produced from GaCl₃(s).

The vessel 32 includes a supply tube 33 which supplies a carrier gas CG, and an exhaust pipe 34 through which the produced GaCl₃ gas is exhausted together with the carrier gas CG.

In a case in which the GaCl₃ gas production apparatus 30 is applied to the above Crystalline GaN film-manufacturing apparatus 100, the exhaust pipe 34 is in communication with the GaCl₃ supply tube 22 of the Crystalline GaN film-manufacturing apparatus 100.

The exhaust pipe 34 and the GaCl₃ supply tube 22 may form an integrated member, or the exhaust pipe 34 and the GaCl₃ supply tube 22 may be separate members connected to each other.

The heating temperature in heating of the solid GaCl₃ in the GaCl₃ gas production apparatus 30 is not particularly limited, and the heating temperature is, for example, from 70° C. to 200° C., preferably from 80° C. to 150° C.

<GaCl₃ Gas Production Apparatus B with Liquid Ga as Raw Material>

The GaCl₃ gas production apparatus B with liquid Ga as a raw material, which can be used, is, for example, a GaCl₃ gas production apparatus B which allows liquid Ga and a Cl₂ gas to react (hereinafter, also referred to as “first stage reaction”), thereby producing a GaCl gas (namely, gallium monochloride) (hereinafter, also referred to as “first step”), and then allows the GaCl gas and a Cl₂ gas to react (hereinafter, also referred to as “second stage reaction”), thereby producing a GaCl₃ gas.

Such a GaCl₃ gas production apparatus B can be appropriately found in the known publication WO 2011/142402.

FIG. 3 is a schematic configuration view illustrating one example of the GaCl₃ gas production apparatus B.

A GaCl₃ gas production apparatus 40 as one example of the GaCl₃ gas production apparatus B includes a reaction tube 42 through which Cl₂ and a carrier gas CG are supplied, and a Ga boat 46 as a vessel which is disposed in the reaction tube 42 and which accommodates Ga(1) (namely, liquid Ga), as illustrated in FIG. 3.

The reaction tube 42 is provided with a Cl₂ inlet 44 downstream (downstream in a flow direction of Cl₂ and a carrier gas CG. The same shall apply hereinafter.) relative to the Ga boat 46. The Cl₂ inlet 44 is an inlet through which a Cl₂ gas is introduced into the reaction tube 42. The Cl₂ gas may be introduced in the state of being diluted with a carrier gas.

The GaCl₃ gas production apparatus 40 allows Cl₂ and a carrier gas CG to be supplied from one end of the reaction tube 42, and allows Cl₂ and Ga(1) supplied to react, thereby producing a GaCl gas (first stage reaction). The produced GaCl gas is transported downstream, and the GaCl gas transported and the Cl₂ gas introduced through the Cl₂ inlet 44 are allowed to react, thereby producing a GaCl₃ gas (second step).

The GaCl₃ gas obtained in the second step is transported further downstream of the reaction tube 42, together with the carrier gas CG.

In a case in which the GaCl₃ gas production apparatus 40 is applied to the Crystalline GaN film-manufacturing apparatus 100, the downstream of the reaction tube 42 is in communication with the GaCl₃ supply tube 22 of the Crystalline GaN film-manufacturing apparatus 100.

The reaction tube 42 and the GaCl₃ supply tube 22 may form an integrated member, or the reaction tube 42 and the GaCl₃ supply tube 22 may be separate members connected to each other.

As described above, the GaCl₃ gas production apparatus 40 is configured from a first zone which is located in an upstream region relative to the Cl₂ inlet 44 and in which the first stage reaction is performed, and a second zone which is located in a downstream region relative to the Cl₂ inlet 44 and in which the second stage reaction is performed.

The following reactions are performed in the first zone (first stage reaction) and the second zone (second stage reaction), respectively.

Reaction in first zone (first stage reaction): Ga(1)+1/2Cl₂(g)→GaCl(g)

Reaction in second zone (second stage reaction): GaCl(g)+Cl₂(g)→GaCl₃(g)

The reaction temperature T1 in the first zone (first stage reaction) is preferably 300° C. or more, more preferably 500° C. or more, particularly preferably 700° C. or more from the viewpoint of an increase in reaction rate.

The upper limit of the reaction temperature T1 is, for example, 1100° C., preferably 1000° C.

The reaction temperature T2 in the second zone (second stage reaction) is not particularly limited and can be selected from a wide range of temperatures, and the lower limit of the reaction temperature T2 is preferably any temperature which does not cause GaCl supplied from the first zone to be precipitated on the wall of the reaction tube. The reaction temperature T2 is preferably 150° C. or more, more preferably 200° C. or more, particularly preferably 500° C. or more from such a viewpoint.

The upper limit of the reaction temperature T2 is, for example, 1100° C., preferably 1000° C.

The amount of the Cl₂ gas supplied through the Cl₂ supply port 44 in the second zone is equal molar to that of GaCl supplied from the first zone to the second zone from the viewpoint of a more enhancement in selectivity of GaCl₃ to be produced.

It is noted, as described above, that, in a case in which the mixed gas of the produced GaCl₃ gas, an excess Cl₂ gas, and the carrier gas CG is purposely transported downstream of the reaction tube 42, the amount of Cl₂ (molar number) supplied through the Cl₂ supply port 44 may be excess to the molar number of GaCl supplied from the first zone to the second zone.

### EXAMPLES

Hereinafter, Examples of the disclosure will be shown, but the disclosure is not intended to be limited to the following Examples.

### Experimental Example 1

(Solid GaCl₃ Raw Material)

The above Crystalline GaN film-manufacturing apparatus 100 (FIG. 1) and GaCl₃ gas production apparatus 30 (FIG. 2) were used, thereby producing a GaCl₃ gas with solid GaCl₃ as a raw material, and the GaCl₃ gas produced was used as a raw material, thereby manufacturing a Crystalline GaN film.

The exhaust pipe 34 of the GaCl₃ gas production apparatus 30 was connected to the GaCl₃ supply tube 22 of the Crystalline GaN film-manufacturing apparatus 100.

The distance between the outlet of each gas in the gas release member 20 and the substrate 10 was 80 mm in the Crystalline GaN film-manufacturing apparatus 100.

All a carrier gas CG, a barrier gas BG, and a purge gas PG here used were N₂ gases.

The flow rate of the barrier gas BG was 6 L/min, the flow rate of the purge gas PG was 8 L/min, and the pressure in the housing 102 was atmospherically relieved (1 atm).

The substrate 10 used was a sapphire (0001) substrate.

A Crystalline GaN film was manufactured according to one example of the above manufacturing process.

First, the barrier gas BG was introduced into the intermediate release section 14 of the gas release member 20 and the barrier gas BG introduced was released from the intermediate release section 14 toward the substrate 10, in the Crystalline GaN film-manufacturing apparatus 100 (see FIG. 1).

Next, a mixed gas of an NH₃ gas and the carrier gas CG was introduced into the outer periphery release section 16 of the gas release member 20, and the mixed gas introduced was released from the outer periphery release section 16 toward the substrate 10. Adjustment was here made so that the pressure of the NH₃ gas (hereinafter, designated as “NH₃ supply pressure a1”) was 0.4 atm, the pressure of the mixed gas of an NH₃ gas and the carrier gas CG was 1 atm, and the flow rate of the mixed gas of an NH₃ gas and the carrier gas CG (hereinafter, designated as “flow rate a1”) was 10 L/min, in the outer periphery release section 16.

Next, the growth section was heated, whereby the substrate 10 was heated to a growth temperature of 1300° C.

Next, solid GaCl₃ in the vessel 32 was heated to 93° C., thereby producing a GaCl₃ gas, and the carrier gas CG was supplied through the supply tube 33 into the vessel 32 at a flow rate of 10 L/min, thereby allowing a mixed gas of the GaCl₃ gas and the carrier gas CG to be exhausted out of the vessel 32 through the exhaust pipe 34, in the GaCl₃ gas production apparatus 30 (see FIG. 2). The mixed gas of the GaCl₃ gas and the carrier gas CG, exhausted, was transported to the GaCl₃ supply tube 22 in the Crystalline GaN film-manufacturing apparatus 100 (see FIG. 1). Adjustment was here made so that the pressure of the GaCl₃ gas (hereinafter, designated as “GaCl₃ supply pressure b1”) was 2.7×10⁻² atm, the pressure of the mixed gas of the GaCl₃ gas and the carrier gas CG was 1 atm, and the flow rate of the mixed gas of the GaCl₃ gas and the carrier gas CG (hereinafter, designated as “flow rate b1”) was 10 L/min, in the GaCl₃ supply tube 22.

In condition 1 (with Cl₂ gas), a Cl₂ gas having a purity of 100% was supplied to the GaCl₃ supply tube 22 through the halogen gas supply tube 24. Adjustment was made in condition 1 so that the pressure of the Cl₂ gas (hereinafter, designated as “Cl₂ supply pressure c1”) was 1 atm and the flow rate of the Cl₂ gas (hereinafter, designated as “flow rate c1”) was 0.2 L/min in the halogen gas supply tube 24.

In condition 1, a mixed gas of the GaCl₃ gas, the Cl₂ gas, and the carrier gas CG was released toward the substrate 10 from the central release section 12 of the gas release member 20 in communication with the GaCl₃ supply tube 22.

In condition 1 (with Cl₂ gas), the timing between the start of supply of the GaCl₃ gas and the carrier gas CG to the GaCl₃ supply tube 22 and the start of supply of the 100% Cl₂ gas via the halogen gas supply tube 24 to the GaCl₃ supply tube 22 was adjusted, whereby supply of the GaCl₃ gas onto the substrate 10 (namely, release of the GaCl₃ gas from the central release section 20 of the gas release member 20) and supply of the Cl₂ gas onto the substrate 10 (namely, release of the Cl₂ gas from the central release section 20 of the gas release member 20) were substantially simultaneously started.

In condition 2 (without Cl₂ gas), the same operation as in condition 1 (with Cl₂ gas) was performed except that the Cl₂ gas having a purity of 100% was changed to a N₂ gas. Adjustment was made in condition 2 so that the pressure of the N₂ gas was 1 atm and the flow rate of the N₂ gas was 0.2 L/min in the halogen gas supply tube 24.

The total gas flow rate in the case of condition 1 (with Cl₂ gas) was determined according to the following calculation formula, and was 34.2 L/min.

$$Total gas flow rate ( L \text{/} min ) ( condition 1 ) = flow rate a 1 + flow rate b 1 + flow rate c 1 + flow rate of barrier gas BG + flow rate of purge gas PG = 10 L \text{/} min + 10 L \text{/} min + 0.2 L \text{/} min + 6 L \text{/} min + 8 L \text{/} min = 34.2 L \text{/} min$$

In the case of condition 1, the partial pressure P_{NH3} of the NH₃ gas, the partial pressure P_{GaCl3} of the GaCl₃ gas, the partial pressure P_{Halogen} of the Cl₂ gas, and the partial pressure ratio [P_{Halogen}/P_{GaCl3}] on the substrate 10 (namely, at a location at a distance of 40 mm away from the substrate 10 toward the gas upstream) are calculated as follows, respectively.

Partial pressure P_{NH3} of NH₃ gas on substrate 10 (condition 1) =
NH₃ supply pressure a1 × (Flow rate a1/Total gas flow rate) =
0.4 atm × (10/34.2) = 0.117 atm
Partial pressure P_{GaCl3} of GaCl₃ gas on substrate 10 (condition 1) =
GaCl₃ supply pressure b1 × (Flow rate b1/Total gas flow rate) =
2.7 × 10⁻² atm × (10/34.2) = 7.89 × 10⁻³ atm
Partial pressure P_{Halogen} of Cl₂ gas on substrate 10 (condition 1) =
Cl₂ supply pressure c1 × (Flow rate c1/Total gas flow rate) =
1 atm × (0.2/34.2) = 5.85 × 10⁻³ atm
Partial pressure ratio [P_{Halogen}/P_{GaCl3}] (condition 1) =
5.85 × 10⁻³ atm/7.89 × 10⁻³ atm = 0.74

The total gas flow rate in the case of condition 2 was equal to the total gas flow rate in the case of condition 1.

The partial pressure ratio [P_{Halogen}/P_{GaCl3}] in the case of condition 2 was, of course, 0.

A Crystalline GaN film was grown under condition 1 or condition 2 as above, and the growth rate of the Crystalline GaN film was confirmed.

The growth rate of the Crystalline GaN film in the case of condition 1 (with Cl₂ gas) was 400 μm/h.

The growth rate of the Crystalline GaN film in the case of condition 2 (without Cl₂ gas) was 36 μm/h.

### Experimental Example 2

(Liquid Ga Raw Material)

The above Crystalline GaN film-manufacturing apparatus 100 (FIG. 1) and GaCl₃ gas production apparatus 40 (FIG. 3) were used, thereby producing a GaCl₃ gas with liquid Ga as a raw material, and the GaCl₃ gas produced was used as a raw material, thereby manufacturing a Crystalline GaN film.

The GaCl₃ supply tube 22 of the Crystalline GaN film-manufacturing apparatus 100 was connected to the downstream of the reaction tube 42 in the GaCl₃ gas production apparatus 40.

The distance between the outlet of each gas in the gas release member 20 and the substrate 10 was 80 mm in the Crystalline GaN film-manufacturing apparatus 100.

All a carrier gas CG, a barrier gas BG, and a purge gas PG here used were N₂ gases.

The flow rate of the barrier gas BG was 6 L/min, the flow rate of the purge gas PG was 8 L/min, and the pressure in the housing 102 was atmospherically relieved (1 atm).

The substrate 10 used was a sapphire (0001) substrate.

A Crystalline GaN film was manufactured according to one example of the above manufacturing process.

First, the barrier gas BG was introduced into the intermediate release section 14 of the gas release member 20 and the barrier gas BG introduced was released from the intermediate release section 14 toward the substrate 10, in the Crystalline GaN film-manufacturing apparatus 100 (see FIG. 1).

Next, a mixed gas of an NH₃ gas and the carrier gas CG was introduced into the outer periphery release section 16 of the gas release member 20, and the mixed gas introduced was released from the outer periphery release section 16 toward the substrate 10. Adjustment was here made so that the pressure of the NH₃ gas (hereinafter, designated as “NH₃ supply pressure a2”) was 0.3 atm, the pressure of the mixed gas of the NH₃ gas and the carrier gas CG was 1 atm, and the flow rate of the mixed gas of the NH₃ gas and the carrier gas CG (hereinafter, designated as “flow rate a2”) was 10 L/min, in the outer periphery release section 16.

Next, the growth section was heated, whereby the substrate 10 was heated to a growth temperature of 1250° C.

Next, both the temperature of the first zone where the first stage reaction [Ga(1)+1/2Cl₂(g)→GaCl(g)] was performed and the temperature of the second zone where the second stage reaction [GaCl(g)+Cl₂(g)→GaCl₃(g)] was performed were adjusted to 850° C. in the GaCl₃ gas production apparatus 40 (see FIG. 3).

(First Stage Reaction: Ga(1)+1/2Cl₂(g)→GaCl(g))

Next, a mixed gas of a Cl₂ gas and the carrier gas CG was introduced onto the Ga boat 46 in the reaction tube 42. Adjustment was here made so that the pressure of the Cl₂ gas was 2×10⁻² atm, the total pressure of the Cl₂ gas and the carrier gas CG was 1 atm, and the mixed gas of the Cl₂ gas and the carrier gas CG was 5 L/min, on the Ga boat 46. Thus, a GaCl gas was produced according to the first stage reaction.

The first stage reaction produces such a CaCl gas in a molar number twice (namely, twofold partial pressure) that of the Cl₂ gas. Such a change in the molar number of any gas by a reaction is hereinafter referred to as “molar change”. Such a molar change allows the volume per unit time (namely, flow rate) to be changed under a constant pressure (1 atm).

The partial pressures of the Cl₂ gas and the carrier gas CG before the first stage reaction are 0.02 atm and 0.98 atm, respectively. The molar change in the first stage reaction allows the total pressure to be imaginarily increased from 1 atm to 1.02 atm. In fact, while a total pressure of 1 atm is kept, the gas flow rate is increased from 5 L/min to 5.1 L/min (calculation formula: 5 L/min×1.02=5.1 L/min). Thus, the pressure of the GaCl gas under a total pressure of 1 atm is actually 0.0392 atm according to the following calculation formula.

$$Pressure of GaCl gas under total pressure of 1 atm = 4 \times 1 {0}^{- 2} atm / ( 5.1 / 5 ) = 4 \times 1 {0}^{- 2} atm / 1.02 = 0.0392 atm$$

As described above, the pressure of the GaCl gas was 0.0392 atm and the flow rate of the mixed gas of the GaCl gas and the carrier gas CG was 5.1 L/min, immediately after passage on the Ga boat 46 in the reaction tube 42.

(Second Stage Reaction: GaCl(g)+Cl₂(g)→GaCl₃(g))

While the above first stage reaction was performed, a Cl₂ gas having a purity of 100% (pressure 1 atm) was introduced through the Cl₂ inlet 44, and a GaCl₃ gas was produced by the second stage reaction. A mixed gas of the GaCl₃ gas produced and the mixed gas of the carrier gas CG was transported to the GaCl₃ supply tube 22 of the Crystalline GaN film-manufacturing apparatus 100 (FIG. 1).

The molar number of the Cl₂ gas introduced through the Cl₂ inlet 44 was set as to be equal to the above molar number of the GaCl gas. Particularly, the flow rate of the Cl₂ gas having a purity of 100% (pressure 1 atm) was 0.02 L/min (calculation formula: 0.0392×5.1=0.02 L/min).

The second stage reaction allows the molar number (partial pressure) of any gas to be decreased to ½ by the molar change. A relationship of “Partial pressure of GaCl₃ gas produced=Partial pressure of GaCl gas=Partial pressure of Cl₂ gas introduced through Cl₂ inlet 44” is satisfied in the second stage reaction in conditions of Example 2.

Accordingly, the pressure of the GaCl₃ gas (hereinafter, designated as “GaCl₃ supply pressure b2”) is 3.92×10⁻² atm and the flow rate of the mixed gas of the GaCl₃ gas and the carrier gas CG (hereinafter, designated as “flow rate b2”) is 5.1 L/min in the GaCl₃ supply tube 22.

In condition 1 (with Cl₂ gas), a Cl₂ gas having a purity of 100% was supplied to the GaCl₃ supply tube 22 through the halogen gas supply tube 24. Adjustment was made in condition 1 so that the pressure of the Cl₂ gas (hereinafter, designated as “Cl₂ supply pressure c2”) was 1 atm and the flow rate of the Cl₂ gas (hereinafter, designated as “flow rate c2”) was 0.2 L/min in the halogen gas supply tube 24.

In condition 1, a mixed gas of the GaCl₃ gas, the Cl₂ gas, and the carrier gas CG was released toward the substrate 10 from the central release section 12 of the gas release member 20 in communication with the GaCl₃ supply tube 22.

In condition 1 (with Cl₂ gas), the timing between the start of supply of the GaCl₃ gas and the carrier gas CG to the GaCl₃ supply tube 22 and the start of supply of the 100% Cl₂ gas via the halogen gas supply tube 24 to the GaCl₃ supply tube 22 was adjusted, whereby supply of the GaCl₃ gas onto the substrate 10 (namely, release from the central release section 20 of the gas release member 20) and supply of the halogen gas onto the substrate 10 (namely, release from the central release section 20 of the gas release member 20) were substantially simultaneously started.

In condition 2 (without Cl₂ gas), the same operation as in condition 1 (with Cl₂ gas) was performed except that the Cl₂ gas having a purity of 100% was changed to a N₂ gas. Adjustment was made in condition 2 so that the pressure of the N₂ gas was 1 atm and the flow rate of the N₂ gas was 0.2 L/min in the halogen gas supply tube 24.

The total gas flow rate in the case of condition 1 (with Cl₂ gas) was determined according to the following calculation formula, and was 29.3 L/min.

$$Total gas flow rate ( L \text{/} min ) ( condition 1 ) = flow rate a 2 + flow rate b 2 + flow rate c 2 + flow rate of barrier gas BG + flow rate of purge gas PG = 10 L \text{/} min + 5.1 L \text{/} min + 0.2 L \text{/} min + 6 L \text{/min} + 8 L \text{/} min = 29.3 \text{L/} min$$

In condition 1, the partial pressure P_{NH3} of the NH₃ gas, the partial pressure P_{GaCl3} of the GaCl₃ gas, the partial pressure P_{Halogen} of the Cl₂ gas, and the partial pressure ratio [P_{Halogen}/P_{GaCl3}] on the substrate 10 (namely, at a location at a distance of 40 mm away from the substrate 10 toward the gas upstream) are calculated as follows, respectively.

$$Partial pressure {P}_{N H 3} of {NH}_{3} gas on substrate 10 ( condition 1 ) = {NH}_{3} supply pressure a 2 \times ( Flow rate a 2 / Total gas flow rate ) = 0.3 atm \times ( 10 / 29 .3 ) = 1.02 \times 1 {0}^{- 1} atm$$

$$Partial pressure {P}_{GaCl 3} of {GaCl}_{3} gas on substrate 10 = {GaCl}_{3} supply pressure b 2 \times ( Flow rate b 2 / Total gas flow rate ) = 3.92 \times 1 {0}^{- 2} atm \times ( 5.1 / 29.3 ) = 6.8 \; 2 \times 1 {0}^{- 3} atm$$

$$Partial pressure {P}_{Halogen} of {Cl}_{2} gas on substrate 10 ( condition 1 ) = {Cl}_{2} supply pressure c 2 \times ( Flow rate c 2 / Total gas flow rate ) = 1 atm \times ( 0.2 / 29 .3 ) = 6.8 \; 3 \times 1 {0}^{- 3} atm$$

$$Partial pressure ratio [ {P}_{H a l o g e n} / {P}_{GaCl 3} ] ( condition 1 ) = 6.83 \times 1 {0}^{- 3} atm / 6. 82 \times 1 {0}^{- 3} = 1.00$$

The total gas flow rate in the case of condition 2 was equal to the total gas flow rate in the case of condition 1.

The partial pressure ratio [P_{Halogen}/P_{GaCl3}] in the case of condition 2 was, of course, 0

A Crystalline GaN film was grown under condition 1 or condition 2 as above, and the growth rate of the Crystalline GaN film was confirmed.

The growth rate of the Crystalline GaN film in the case of condition 1 (with Cl₂ gas) was 360 μm/h.

The growth rate of the Crystalline GaN film in the case of condition 2 (without Cl₂ gas) was 35 μm/h.

### Experimental Example 3

The growth rate of a Crystalline GaN film (μm/n) at each partial pressure ratio [P_{Halogen}/P_{GaCl3}] shown in Table 1 was measured with respect to each case of condition A and condition B shown in Table 1, based on Experimental Example 1 (solid GaCl₃ raw material).

The results are shown in Table 1. In Table 1, “N.D.” means no measurement result (No Data).

TABLE 1

| Condition A | | Condition B | |
|---|---|---|---|
| Growth temperature: 1250° C. | | Growth temperature: 1375° C. | |
| Partial pressure P_{GaCl3} of GaCl₃ on substrate: 4.5 × 10⁻³ atm | | Partial pressure P_{GaCl3} of GaCl₃ on substrate: 7.5 × 10⁻³ atm | |
| Partial pressure P_{NH3} of NH₃ on substrate: 0.1 atm | | Partial pressure of NH₃ on substrate: 0.2 atm | |
| Partial pressure ratio | Growth rate | Partial pressure ratio | Growth rate |
| [P_{Halogen}/P_{GaCl3}] | (μm/h) | [P_{Halogen}/P_{GaCl3}] | (μm/h) |
| 0 | 35 | 0 | 55 |
| 0.50 | 70 | 0.05 | N.D. |
| 0.10 | 80 | 0.10 | 150 |
| 0.15 | 110 | 0.15 | N.D. |
| 0.20 | 170 | 0.20 | 280 |
| 0.25 | 200 | 0.25 | N.D. |
| 0.30 | 240 | 0.30 | 390 |
| 0.35 | 260 | 0.35 | N.D. |
| 0.40 | 260 | 0.40 | 410 |
| 0.60 | 260 | 0.60 | 410 |
| 0.80 | 255 | 0.80 | 405 |
| 1.00 | 260 | 1.00 | 410 |
| 1.30 | 260 | 1.30 | 410 |
| 1.60 | 255 | 1.60 | 400 |
| 1.80 | 260 | 1.80 | 410 |
| 2.00 | 250 | 2.00 | 400 |
| 2.20 | 240 | 2.20 | 380 |
| 2.50 | 230 | 2.50 | 390 |

It was confirmed as shown in Table 1 that the growth rate of the Crystalline GaN film was remarkably increased at a partial pressure ratio [P_{Halogen}/P_{GaCl3}] of 0.20 or more (in particular, 0.30 or more) in both the cases of condition A and condition B.

### Experimental Example 4

The relationship between the partial pressure of GaCl₃ on the substrate and the growth rate of a Crystalline GaN film (μm/n) was measured with respect to each case of condition C (with Cl₂) and condition D (without Cl₂) shown in Table 2, based on Experimental Example 1 (solid GaCl₃ raw material).

The results are shown in Table 2.

TABLE 2

| Condition C (with Cl₂) | | Condition D (without Cl₂) | |
|---|---|---|---|
| Growth temperature 1300° C. | | Growth temperature 1300° C. | |
| Partial pressure P_{NH3} of NH₃ on substrate: 0.1 atm | | Partial pressure P_{NH3} of NH₃ on substrate: 0.1 atm | |
| Partial pressure ratio [P_{Halogen}/P_{GaCl3}]: 1.00 | | Partial pressure ratio [P_{Halogen}/P_{GaCl3}]: 0 | |
| Partial pressure P_{GaCl3} of | | Partial pressure P_{GaCl3} of | |
| GaCl₃ on substrate | Growth rate | GaCl₃ on substrate | Growth rate |
| [10⁻³ atm] | (μm/h) | [10⁻³ atm] | (μm/h) |
| 0.1 | 10 | 0.1 | 5 |
| 0.2 | 20 | 0.2 | 10 |
| 0.5 | 80 | 0.5 | 20 |
| 1.0 | 50 | 1.0 | 25 |
| 2.5 | 130 | 2.5 | 30 |
| 4.5 | 250 | 4.5 | 30 |
| 7.5 | 370 | 7.5 | 40 |
| 10.0 | 530 | 10.0 | 50 |

As shown in Table 2, the growth rate was almost not increased even in an increase in the partial pressure of GaCl₃ as a Ga source in the case of condition D (without Cl₂; partial pressure ratio [P_{Halogen}/P_{GaCl3}]=0). The reason was considered because even such an increase in the partial pressure of GaCl₃ as a Ga source caused the amount of increase of the GaCl₃ gas according thereto to be consumed for the reaction with the NH₃ gas in a vapor phase (namely, production of a GaN particle), not resulting in any contribution to an increase in the growth rate of a Crystalline GaN film.

On the contrary, the growth rate was substantially monotonically increased according to an increase in the partial pressure of GaCl₃ as a Ga source in the case of condition C (with Cl₂; partial pressure ratio [P_{Halogen}/P_{GaCl3}]=1.00). The reason was considered because not only the GaCl₃ gas, but also the Cl₂ gas was present to thereby suppress the reaction of the GaCl₃ gas with the NH₃ gas in a vapor phase (namely, production of a GaN particle), resulting in effective contribution of an increase in the amount of the GaCl₃ gas, according to an increase in the partial pressure of GaCl_{3,} to an increase in the growth rate of a Crystalline GaN film.

### Experimental Example 5

(Observation of Attachment of GaN Particle to Susceptor)

A Crystalline GaN film was grown on the substrate for 1 hour in conditions (namely, conditions without any Cl₂ gas) of a growth temperature of 1300° C., a partial pressure P_{GaCl3} of GaCl₃ on the substrate, of 4.5×10⁻³ atm, a partial pressure P_{NH3} of the NH₃ gas on the substrate, of 0.1 atm, and a partial pressure ratio [P_{Halogen}/P_{GaCl3}] of 0, based on Experimental Example 1 (solid GaCl₃ raw material).

Thereafter, the susceptor to which the substrate was mounted was visually observed, and an appearance photograph was taken (FIG. 4).

FIG. 4 is an appearance photograph of the susceptor 104 in the case of manufacturing a Crystalline GaN film onto the substrate 10 in a condition of a partial pressure ratio [P_{Halogen}/P_{GaCl3}] of 0.

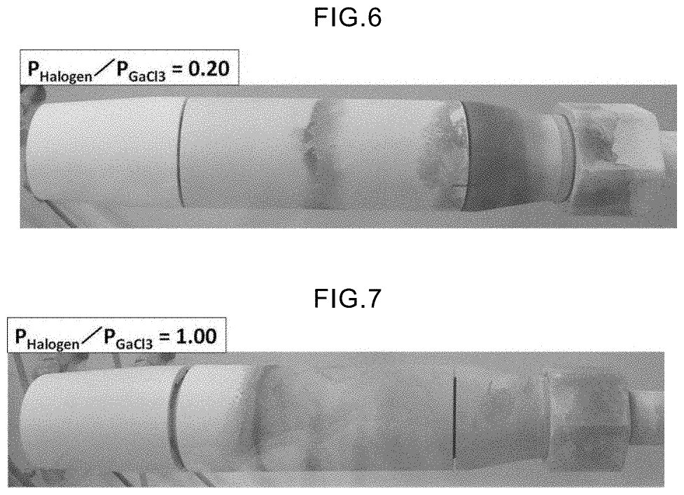

The substrate 10 was mounted to a left end of the susceptor illustrated in FIG. 4, the left end being defined according to FIG. 4 (the same shall apply to FIGS. 6 and 7 described below).

As illustrated in FIG. 4, a powder of yellowish-white color (hereinafter, “yellowish-white powder”) was thickly attached onto the outer periphery (particularly, a region including a region X surrounded by a dotted circle) of the susceptor 104.

Next, the yellowish-white powder in the region X surrounded by a dotted circle in FIG. 4 was subjected to photoluminescence (PL) spectrum measurement with a He—Cd laser (325 nm) at room temperature. The results are represented in FIG. 5.

FIG. 5 is a photoluminescence (PL) spectrum of the yellowish-white powder attached onto the outer periphery (particularly, the region X surrounded by a dotted circle in FIG. 4) of the susceptor in the case of manufacturing a Crystalline GaN film onto the substrate in a condition of a partial pressure ratio [P_{Halogen}/P_{GaCl3}] of 0.

As represented in FIG. 5, a peak at 1.88 eV, derived from composite luminescence of impurities of GaN and defects, and a peak at 3.40 eV, derived from luminescence near the end of a band of GaN were observed in such a PL spectrum.

It was confirmed from the above results that the yellowish-white powder attached onto the outer periphery of the susceptor was a GaN particle.

It was considered from the foregoing results that a GaN particle was produced by reaction of the GaCl₃ gas with the NH₃ gas in a vapor phase and the GaN particle produced was transported downstream relative to the substrate 10 and finally attached onto the outer periphery of the susceptor 104 in the growth step (partial pressure ratio [P_{Halogen}/P_{GaCl3}]=0) of a Crystalline GaN film onto the substrate.

Next, a Crystalline GaN film was grown on the substrate for 1 hour in the same manner as described above except that the condition was changed to any condition with a Cl₂ gas (two respective conditions of partial pressure ratios [P_{Halogen}/P_{GaCl3}] of 0.20 or 1.00).

Thereafter, the susceptor to which the substrate was mounted was visually observed, and an appearance photograph was taken (FIG. 6 and FIG. 7).

FIG. 6 is an appearance photograph of a susceptor in the case of manufacturing a Crystalline GaN film onto the substrate in a condition of a partial pressure ratio [P_{Halogen}/P_{GaCl3}] of 0.20.

FIG. 7 is an appearance photograph of a susceptor in the case of manufacturing a Crystalline GaN film onto the substrate in a condition of a partial pressure ratio [P_{Halogen}/P_{GaCl3}] of 1.00.

It was confirmed as illustrated in FIG. 6 and FIG. 7 that the amount of the yellowish-white powder on the outer periphery of the susceptor was reduced under conditions of partial pressure ratios [P_{Halogen}/P_{GaCl3}] of 0.20 and 1.00.

It was confirmed from the results that the reaction of the GaCl₃ gas with the NH₃ gas (namely, production of a GaN particle as the yellowish-white powder) in a vapor phase was suppressed in the growth step of a Crystalline GaN film onto the substrate (in a condition of a partial pressure ratio [P_{Halogen}/P_{GaCl3}] of 0.20 or more).

The disclosure of Japanese Patent Application Laid-Open (JP-A) No. 2017-177097 filed on Sep. 14, 2017 is herein incorporated by reference in its entity.

All documents, patent applications, and technical standards described herein are herein incorporated by reference, as if each individual document, patent application, and technical standard were specifically and individually indicated to be incorporated by reference.

1. A method of manufacturing a crystalline gallium nitride film, comprising:
a growth step in which a GaCl₃ gas, a halogen gas, an NH₃ gas, and a carrier gas consisting of one or more inert gases are supplied onto a substrate, thereby growing a crystalline gallium nitride film on the substrate,
wherein a partial pressure ratio [P_{Halogen}/P_{GaCl3}] is defined as a ratio of a partial pressure of the halogen gas with respect to a partial pressure of the GaCl₃ gas on the substrate in the growth step, and the partial pressure ratio [P_{Halogen}/P_{GaCl3}] is 0.20 or more.

2. The method of manufacturing a crystalline gallium nitride film according to claim 1, wherein the partial pressure ratio [P_{Halogen}/P_{GaCl3}] is 0.30 or more.

3. The method of manufacturing a crystalline gallium nitride film according to claim 1, wherein the partial pressure ratio [P_{Halogen}/P_{GaCl3}] is 2.50 or less.

4. The method of manufacturing a crystalline gallium nitride film according to claim 1, wherein supply of the GaCl₃ gas onto the substrate and supply of the halogen gas onto the substrate are substantially simultaneously started in the growth step.

5. The method of manufacturing a crystalline gallium nitride film according to claim 1,
wherein a mixed gas A comprising the GaCl₃ gas, the halogen gas, and the carrier gas consisting of one or more inert gases; and a mixed gas B comprising the NH₃ gas, and the carrier gas consisting of one or more inert gases; are supplied onto the substrate in the growth step.

6. The method of manufacturing a crystalline gallium nitride film according to claim 1, wherein the halogen gas is a Cl₂ gas.

7. The method of manufacturing a crystalline gallium nitride film according to claim 1, wherein a temperature of the substrate in the growth step is from 1200° C. to 1550° C.
